(19) United States
(12) Patent Application Publication
(10) Pub. No.: US 2005/0133082 A1
(43) Pub. Date: Jun. 23, 2005

(54) Integrated solar energy roofing construction panel

(76) Inventors: Annemarie Hvistendahl Konold, Malibu, CA (US); Donald Ross Konold, Malibu, CA (US)

Correspondence Address: JACK FOY CAMPBELL, 1702 MAPLE ST., SANTA MONICA, CA, 90405, US

(21) Appl. No.: 10/743,683

(22) Filed: Dec. 20, 2003

(51) Int. Cl. H01L 25/00

(52) U.S. Cl. 136/246

(57) ABSTRACT

A solar assembly comprising two components: a multi-functional solar collecting apparatus and a mounting embedment integrated with building construction material. The mounting embedment component is affixed to a building frame structure using standard construction techniques and receives the multi-functional solar collecting apparatus that is secured with fasteners. The multi-functional solar collecting apparatus converts solar energy to electrical energy using a photovoltaic grid mounted on a copper plate that provides even temperature dispersion across the plate and acts as a thermal radiator when the apparatus is used as a radiant cooler; and a plurality of interconnected heat transfer tubes located within the apparatus enclosure disposed on the plane below the copper plate but conductively coupled to the copper plate for converting the solar energy to thermal energy in a fluid disposed within the heat transfer tubes.

### CROSS-REFERENCE TO RELATED APPLICATIONS

Not Applicable

### STATEMENT REGARDING FEDERALLY SPONSORED RESEARCH OR DEVELOPMENT

Not applicable

### REFERENCE TO A “SEQUENCE LISTING,” A TABLE, OR A COMPUTER PROGRAM LISTING APPENDIX SUBMITTED ON A COMPACT DISC

Not Applicable

### BACKGROUND OF THE INVENTION

(1) Field of the Invention

The present invention relates to the use of solar energy for conversion of solar energy to electrical and thermal energy with the added function of radiant cooling for general use with industrial/commercial processes requiring working fluid cooling; and improved by providing a prepared embedment component integrated with roofing or insulation materials to simplify the invention installation and to shorten the amount of required labor.

(2) Description of the Related Art

Over the last several decades, great strides have been made in the development of apparatus for the conversion of solar energy to thermal or electrical energy or both simultaneously for consumer and industrial applications. U.S. Pat. No. 4,315,163 describes a multipower electrical system for supplying electrical energy to a house including a solar photovoltaic array, a battery charger and DC to AC inverter. U.S. Pat. No. 4,147,157 describes an active solar energy system comprising an array of solar collectors for both generating power for a pump and for heating a fluid, a pumping device powered by the array to circulate the heated fluid and a storage tank to contain the heated fluid. Similarly, U.S. Pat. No. 5,293,447 describes a system for heating water using solar energy comprising a photovoltaic array, a water heater and a controller.

Multi-functional solar collectors were later developed for simultaneously converting solar energy to thermally heat a working fluid and provide DC electrical current in one common apparatus. For example, U.S. Pat. No. 4,392,008 describes a flat plated solar thermal collector below and in spaced conductive relationship to a plate-mounted array of photovoltaic cells. U.S. Pat. No. 5,522,944 describes an apparatus with an array of photovoltaic cells and a plurality of interconnected heat collecting tubes disposed on the same plane with the array.

Other systems attempting to optimize electrical energy conversion and provide conversion to thermal energy from solar energy have been proposed. For example, U.S. Pat. No. 4,373,308 describes a solar cell array consisting of individually rotatable, elongated segments driven by a sun tracker and motor with a thermal solar collector supported beneath the solar cell array for utilization of solar energy received through a roof opening in a building. U.S. Pat. No. 6,018,123 describes a solar cell module provided at the position of a heat collecting plate inside a heat collector in which hot air can be led into a house while maintaining the performance of solar cells.

Recent developments have involved the application of thin-film photovoltaic devices that are attached directly to a roofing surface by an adhesive as disclosed in U.S. Pat. No. 6,553,729 or insulatingly mounted with a resin on a steel sheet that is used conventionally as a roofing material as disclosed in U.S. Pat. No. 6,541,693. These devices save on installation time and cost with minimal installation preparation; however, they are capable of only converting solar energy into electrical DC current and have no inherent capability to heat the photovoltaic device's top surface allowing for melting of snow or ice for applications in winter conditions or cold climates.

Therefore, there is an unmet need in the art for solar collecting devices that are light weight, integrate construction roofing materials within their design for direct installation using standard construction techniques, and convert solar energy to both thermal and electrical energy efficiently in colder climates by adding a function to radiate heat to both cool fluids and keep the solar collectors free of snow and ice.

### BRIEF SUMMARY OF THE INVENTION

The invention is an improvement to an existing multi-function solar collector panel concept that performs a function for solar energy conversion into electrical current, a solar energy heating function for heating a working fluid and a heat radiator function to radiate heat, for melting snow or ice in cold climate applications or for other purposes, within a single enclosure. The improvement incorporates an embedment integrated with building construction material and solar collector panel embedment interface to save on installation costs and labor required installing a solar collector panel. Additional improvements provide for a lighter, more compact design by utilizing thinner, smaller cross-section component materials. Enhancements for fire protection and water runoff collection for non-potable usage are also provided. The incorporation of the embedment integrated with building materials and the solar panel with integrated embedment interface and the other enhancements provides a smaller, light weight solar collector panel with installation cost savings and functionality that previous inventions do not provide.

Included within a single enclosure is a photovoltaic grid that converts solar energy into electrical energy, a thermally conductive heat transfer sheet disposed on a plane below the photovoltaic grid. The heat transfer sheet converts the solar energy in thermal energy uniformly distributed over the entire sheet. On a plane below the sheet but thermally coupled to the sheet by a thermal conductive compound are copper tubes which impart the thermal energy from the sheet to a fluid disposed inside the tube heating the fluid to a high temperature before being discharged from the enclosure.

In a radiator mode, a hot fluid is introduced to the copper tubes that absorb the heat form the fluid, cooling the fluid. This thermal energy is conducted from the tubes to the heat transfer sheet that radiates the thermal energy through the photovoltaic grid and out through the top of the enclosure. This heating ability allows operation of the collector in cold climates preventing the build up of ice and snow on the collector.

The collector panel has applied to the bottom surface a 40 mil waterproof, self-sealing membrane with adhesive applied to one side. This membrane is secured to the bottom surface by the adhesive.

An embedment component is provided that integrates within its design roof or decking sheathing or solid insulator construction material. Applied to the top surface is a second 40 mil waterproof, self-sealing membrane with adhesive applied to one side. The membrane is secured to the sheathing by the adhesive

The exposed, non-adhesive, side of the membrane attached to the roof or deck sheathing is then coated with a layer of lap cement and covered with a light weight fiberglass and asphalt-based sheathing, which is, in turn, coated with lap cement.

Where required by the local building code, a solid insulation board whose thickness is also mandated by the code requirements, is first placed on top of the exposed, non-adhesive, side of the membrane and then coated with a layer of lap cement and covered with a light weight fiberglass and asphalt-based sheathing, which is, in turn, coated with lap cement.

With the lap cement still wet, the solar panel is placed over the lightweight sheath and attached with stainless steel screws, which are of length so that they penetrate only approximately half way through the wooden main sheathing as an additional measure, in addition to the self sealing membranes, to preclude water from leaking through any part of the sheathing.

Internal component improvements were made that allow for a more compact collector envelope that is provided in several construction sizes: 4 feet by 8 feet by 2.0 inches and 2 feet by 8 feet by 2.0 inches. These same improvements also result in a lighter panel.

These internal improvements are as follows. A thinner 0.15-inch Photovoltaic grid without the aluminum frame placed upon a 0.10-inch vinyl substrate replaces the standard Photovoltaic grid in one configuration. In another configuration a thin-film Photovoltaic grid is deposited directly upon the 0.10-inch vinyl substrate. The frame housing and the bottom sheet housing the solar collector component layers is a thinner 0.125-inch aluminum material. A thinner 0.0625-inch copper sheet is used. The copper tubing heat exchanger is designed with smaller diameter 0.5-inch tubing. A 0.5-inch fiberglass grid back plane provides structural support. Different embodiments employ an alternate all aluminum tubing heat exchanger or a copper or aluminum thin profile water tank used in place of the copper tubing heat exchanger.

A capability to interconnect individual solar collector panels into series/parallel arrays is provided. Electrical connections between the panels within the arrays are made with quick connect, snap-in, watertight, weatherproof plugs and receptacles. The array electrical end connections are made with rectangular conduits, or raceways, fitted with the quick connect receptacles mounted within the raceways. In this manner, the only loose conduits or wiring is limited to connection of the raceways to the main system junction boxes below the roof or deck at the system central control station. Circuit protection fuses are installed at the control station for each array. The raceways are pre assembled at the factory prior to system installation at the site.

Similarly, the liquid connections between the panels of an array are made with rapid attaching copper pipe nuts and nipples. The array end liquid connections are made with copper pipe manifolds fitted with copper pipe nuts that engage the Pipe nipples of the last, lower, panels in the arrays. In this manner, the only loose plumbing is limited to connection of the manifolds to the main system liquid storage tanks below the roof or deck at the system central control station. The Manifolds are pre assembled at the factory prior to system installation at the site.

The rainwater runoff collection system consisting of collection trough, water filter, storage tank, and plumbing, provides an additional, self-contained, water supply in areas with sufficient rainfall. The collection trough is attached to the lower edge of the panel array when installed on a slanted roof or deck.

A temperature sensor is provided so that when the sensor output signal is coupled to a microprocessor-based controller, thermostat or Proportional-Integral-Derivative (PID) controller, fluid flow rate can be regulated as a function of its discharge temperature. By this method, fluid discharged from the collector can be maintained at a constant temperature. Since this temperature is also proportional to the photovoltaic grid temperature, the photovoltaic operating temperature can maintained within the preferred range of 70° F. to 100° F. which is the range where the photovoltaic grid is most efficient.

This improved design for a solar collector apparatus is a direct replacement for the inventor's previous design described in U.S. Pat. No. 6,630,622. The features and functions described in that patent are incorporated in this design by reference.

### BRIEF DESCRIPTION OF THE SEVERAL VIEWS THE DRAWINGS

FIG. 1 shows the Solar Collector Panel and the external arrangement of electrical connectors and liquid connectors.

FIG. 2 is a sectional view showing the Solar Collector Panel and its associated Embedment Component. This view illustrates both the internal design of the Solar Collector Panel and the various material layers that comprise the Embedment Component and its interface to the Solar Collector Panel.

FIG. 3 shows an embodiment of the Solar Collector Panel with Fresnel Lenses and the external arrangement of liquid inlet/outlet fittings and louvers.

FIG. 4 is a sectional view showing the Solar Collector Panel with Fresnel Lenses, and its associated Embedment Component. This view illustrates both the internal design of the Solar Collector Panel, the Fresnel lens mounting arrangement and the various material layers that comprise the Embedment Component and its interface to the Solar Collector Panel.

FIG. 5 illustrates an example Array of 24 interconnected Solar Collector Panels and their common liquid and DC current connections.

FIG. 6 shows the same Array of 24 interconnected Solar Collector Panels with the added Two Piece, Split Plastic Electrical Snap-In Conduit and Copper Pipe Liquid Connection Manifold details.

FIG. 7 shows the same Array of 24 interconnected Solar Collector Panels with the added Rain Runoff Collection Trough details.

FIG. 8 illustrates the interconnection of the Solenoid Valve and Sprinkler Head Unit and the Quick-Connect Snap-In Electrical Connector Plugs.

FIG. 9 details the Two Piece, Split, Plastic, Electrical, Snap-In Conduit and the Copper, Pipe, Liquid, Connection Manifold.

FIG. 10 illustrates the cross-section of the Example Array as installed on a typical roof wooden joist structure. As shown, each Solar Collector Panel is mounted on the Embedment Component that is, in turn, mounted on wooden joist structure.

FIG. 11 illustrates the same installation as shown in FIG. 10 with the addition of the Solid Roof Insulation layer in the Embedment Component when required by local building codes.

FIG. 12 illustrates the Solar Panel connectivity for the liquid heat transfer application.

FIG. 13 illustrates the Solar Panel connectivity for the electrical power application.

### DETAILED DESCRIPTION OF THE INVENTION

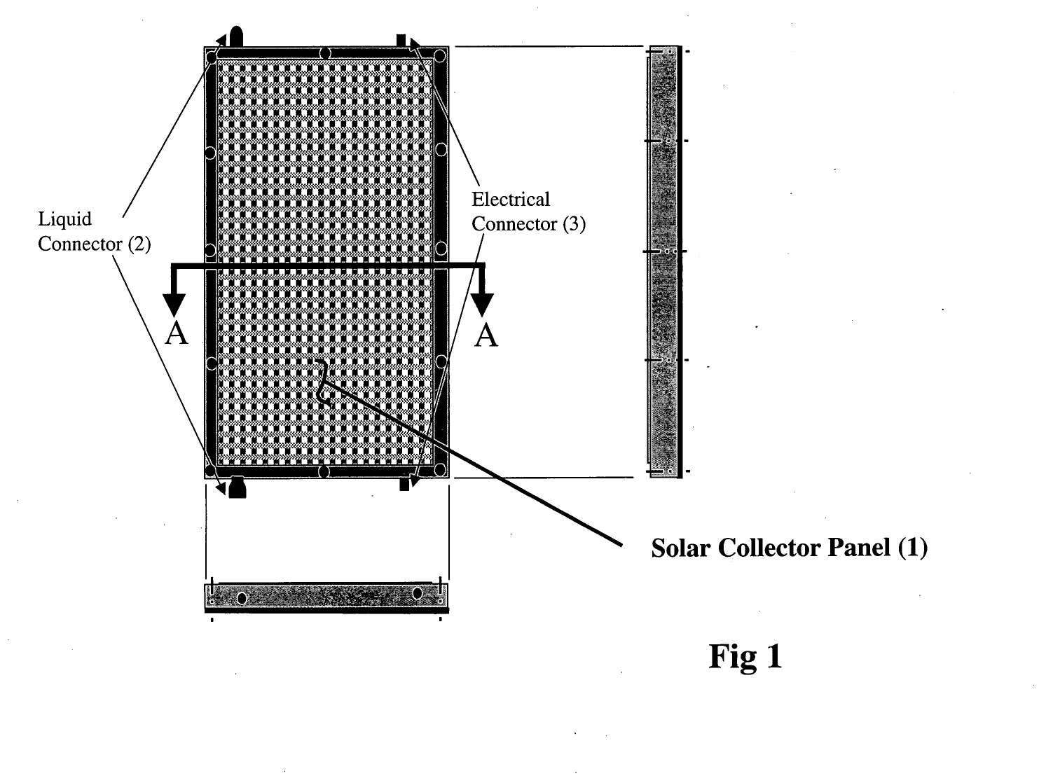

The invention is an improved, compact Solar Collector Panel (1) apparatus in the form of a roof construction material, equivalent for building construction purposes to other common roofing materials, while simultaneously providing electric power and heat collection and dissipation. This panel incorporates an embedment component that integrates building construction materials within the Solar panel assembly, permitting the assembly to serve as a roofing material. As shown in FIG. 1, the Solar Collector Panel (1) is a self-contained, compact Solar Photovoltaic and heat energy absorption or dissipation unit that provides electric power and liquid heat transfer from within a single integrated unit. Power is provided through electrical connectors (3) while cold liquid enters and heated liquid is removed from the panel through liquid connectors (2). The compact collector Panel (1) is provided in standard sizes, the most common being 4 feet by 8 feet and 2 feet by 8 feet with a height of 2.0 inches.

The Solar panel construction system is provided using three forms of Photovoltaic Solar panel in the electric power segment, the conventional units grouped into 4 by 8 foot construction panels, the thin-film photovoltaic strips grouped into the 4 by 8 foot construction panels, and either the conventional or thin-film PV materials combined with Fresnel magnification lenses for greater efficiency.

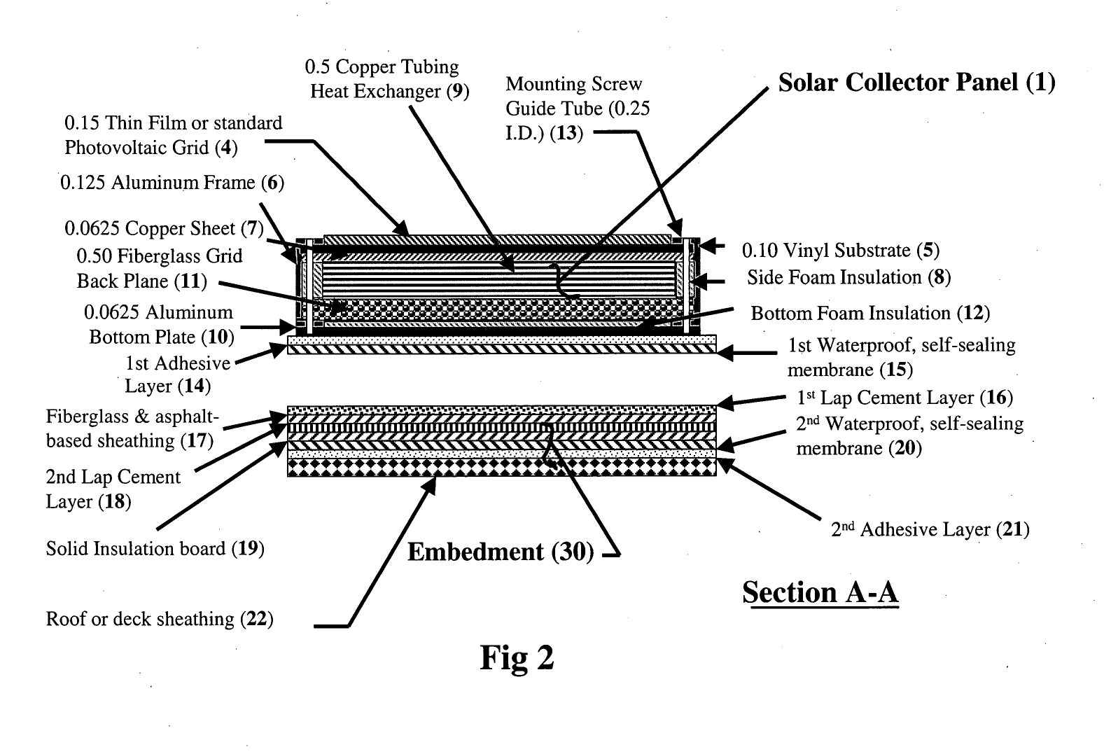

As a first embodiment of the apparatus, FIG. 2, is a section view A-A of the solar collector panel (1) and a separate embedment assembly that are both constructed as a sandwich of component layers. The collector components are contained within a rectangular frame with an open topside and an open bottom side. The first layer of the Solar Panel (1) is a photovoltaic (PV) grid (4) held in place by an overlaying lip formed on the top of frame (6) side members. The PV grid includes a thin glass cover sheet for weather protection. Supporting the photovoltaic grid (4) is a 0.10-inch clear Vinyl substrate (5). The photovoltaic grid (4) consists of multiple commercial thin film or crystalline cell panel units available from sources such as UniSolar, Sharp, Kyocera, and Shell. Below the PV grid is mounted a 0.0625-inch copper sheet (7) for uniform and efficient heat transfer as absorption and radiation to or from a copper tubing heat exchanger (9). For maximum heat transfer, the copper tubing heat exchanger (9) is bonded to the copper sheet (7) using a thermal conducting compound. In the preferred embodiment, the compound is a copper-filled epoxy. To minimize heat loss to the sides or bottom of the panel (1), the copper tubing heat exchanger (9) is thermally isolated by side and bottom foam insulation (8, 12) that lies between the copper tubing heat exchanger (9), the frame (42), and the bottom plate (10). Below the copper tubing heat exchanger (9) is a 0.50-inch fiberglass back plane (11) that provides rigid structural support for the heat exchanger (9) and the photovoltaic grid (4). This layer is followed by a bottom foam insulation (12) layer that thermally isolates the back plane (11) layer from a 0.0625-inch aluminum bottom plate (10). Rivets secure the bottom plate (10) so that the entire collector panel sandwich is firmly held in place.

The improvement includes a first waterproof, self-sealing, membrane (15) with a top surface and an opposed bottom surface has a first adhesive layer (14) applied to its top surface. The first waterproof, self-sealing, membrane (15) is secured to the bottom cover plate (10) by the first adhesive layer.

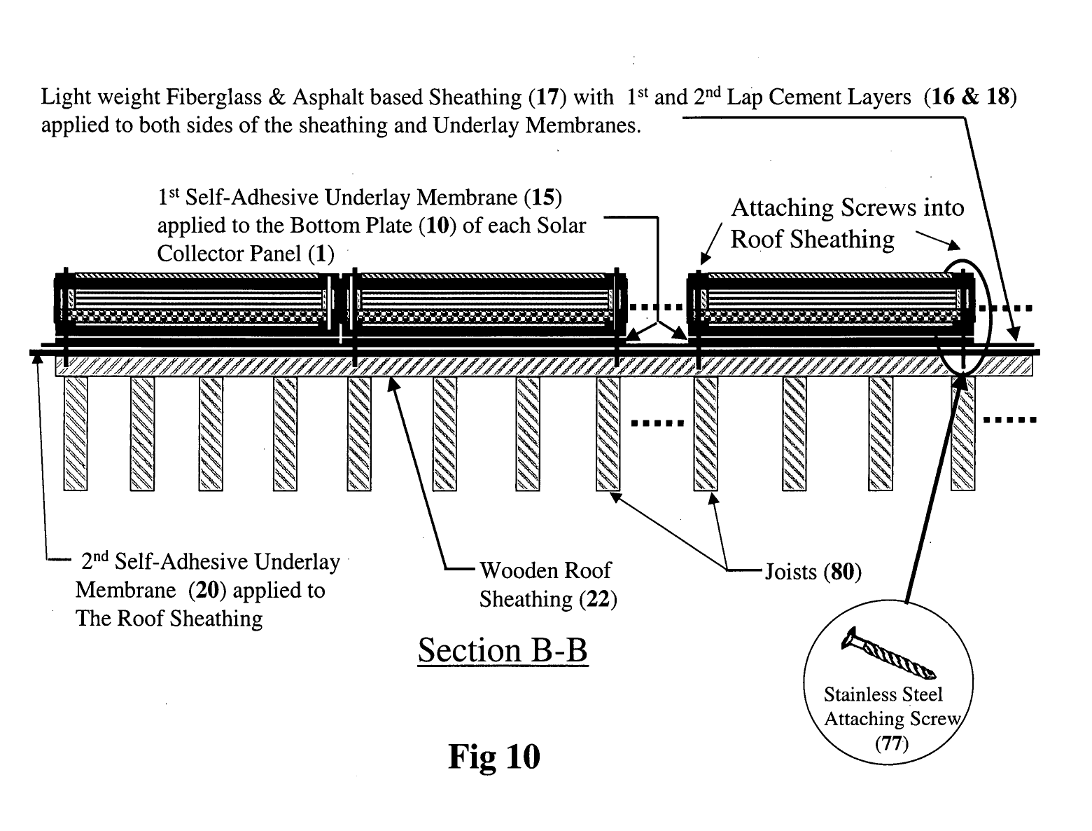

Evenly, disposed around each side of the frame (42) as show in FIGS. 1 and 2 are mounting screw guide tubes (13) that extend the entire depth of the collector panel (1) from the top of the frame (42) through the aluminum bottom plate (10). As seen in FIG. 10, the guide tubes retain mounting screws (77) that secure the panels to the roof sheathing, with the screws penetrating part way into the roof sheathing.

Again, as shown in FIG. 2 section view A-A of the solar collector panel (1) a second embodiment of the apparatus is formed where the first layer is a thin-film photovoltaic grid (4) vacuum deposited on a 0.10-inch clear Vinyl substrate (5). The Vinyl substrate (5) is held in place by an overlaying lip formed on the top of frame (42) side members. Below that is mounted a heat transfer 0.0625-inch copper sheet (7) for uniform and efficient heat absorption and radiation. For maximum heat transfer, a copper tubing heat exchanger (9) is bonded to the copper sheet (7) using a thermal conducting compound. In the preferred embodiment, the compound is a copper-filled epoxy. The copper tubing heat exchanger (9) is thermally isolated by side foam insulation (8) that lies between the copper tubing heat exchanger (9) and the frame (42).

Below the copper tubing heat exchanger (9) is a 0.50-inch fiberglass back plane (11) that provides rigid structural support for the heat exchanger (9) and the photovoltaic grid (4). This layer is followed by a bottom foam insulation (12) layer that thermally isolates the back plane (11) layer from a 0.0625-inch aluminum bottom plate (10). Rivets secure the bottom cover plate (10) so that the entire collector panel sandwich is firmly held in place.

A first waterproof, self-sealing, membrane (15) with a top surface and an opposed bottom surface has a first adhesive layer (14) applied to its top surface. The first waterproof, self-sealing, membrane (15) is secured to the bottom cover plate (10) by the first adhesive layer.

Evenly, disposed around each side of the frame (42) as shown in FIGS. 1 and 2 are mounting screw guide tubes (13) that penetrate the entire depth of the collector panel from the top of the frame (42) through the aluminum bottom plate (10).

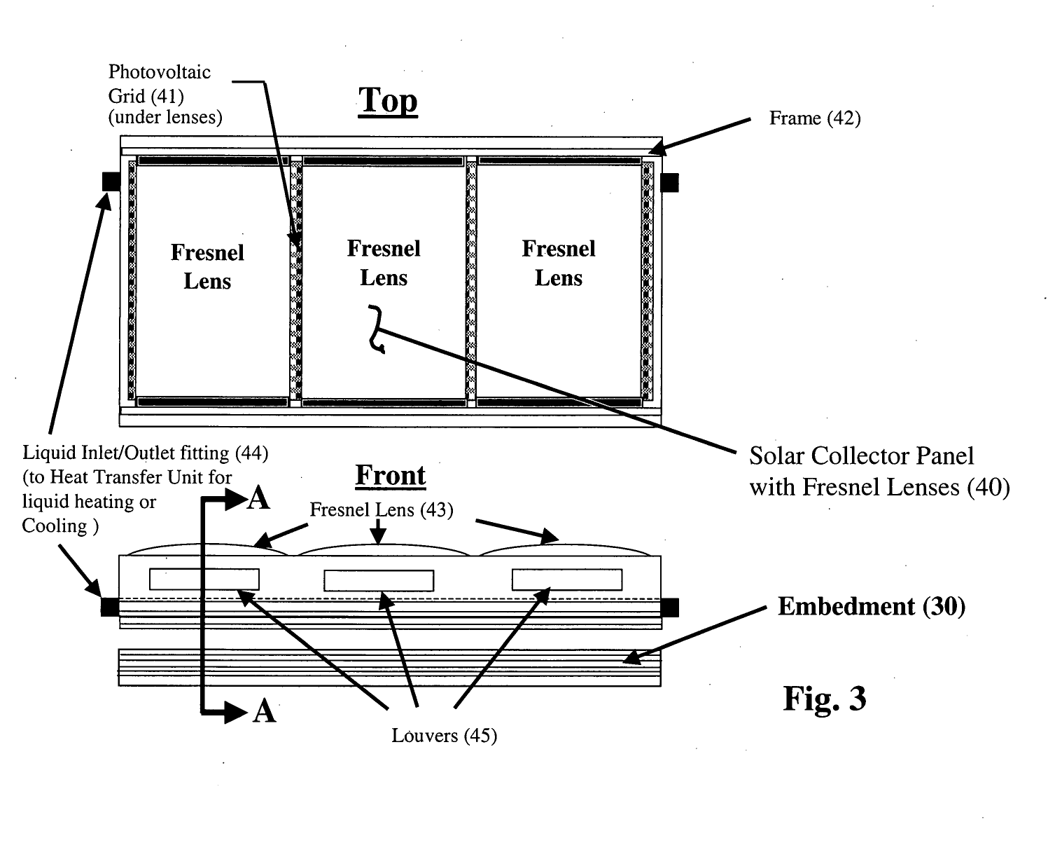

FIG. 3 shows another embodiment that is an improvement to the inventor's design patented under U.S. Pat. No. 6,630,622 whose design features are incorporated by reference. This embodiment is a Solar Collector Panel (40) comprising the Photovoltaic (PV) grid (41), an internal the copper tubing heat exchanger (48), and the Fresnel lens (43) assembly with Louvers (45). The Fresnel lens (43) assembly is employed to increase the Solar electric and heat energy capturing capacity of the panel. Through its shape, the Fresnel lens (43) assembly also provides static Sun tracking to maximize solar energy capture, without the use of mechanical rotating or positioning mechanisms. The Fresnel lens (43) provide this enhancement on days of partial overcast as well as on Sunny days

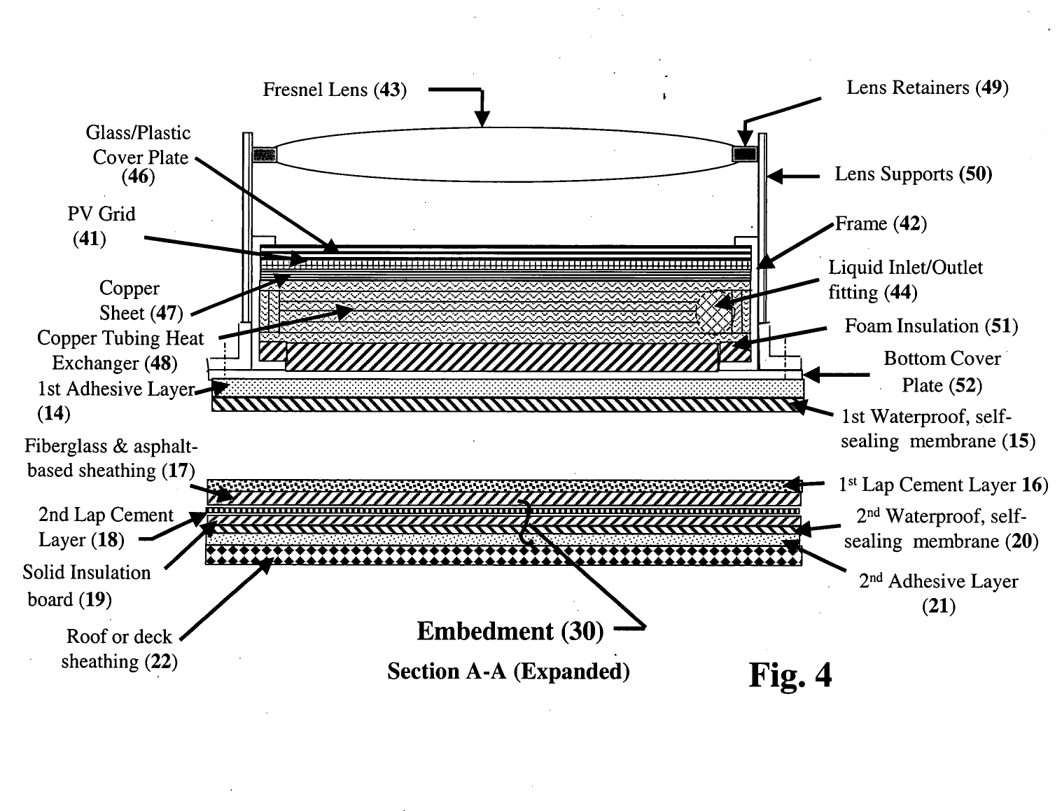

FIG. 4 gives the detailed design of the integrated Solar Collector Panel with Fresnel Lenses (40). As shown, Aluminum lens supports (50) are riveted along the length of each side of the frame (42). The height of these supports are selected to allow positioning of the lens assembly 6.5 to 7.5 inches above a bottom surface of a glass/plastic. cover plate (46) depending upon the panel size or 5.5 inches above a top surface of the glass/plastic cover plate (46). This distance was selected to ensure that the focal point of the Fresnel lens (43) lies below the plane of the photovoltaic grid (41) so that hot spots due to insolation magnification don't form on the grid.

As seen in FIG. 3, openings, or louvers (45), are provided in the lens supports (50) with movable sections to control air and rain flow across the grid surface. For cold climate installation, the louvers (45) are opened for maximum heat radiation, airflow, and release of impingent snow and ice. For warm climate installation, the lens support louvers (45) are closed to preclude the leakage of captured heat, which would otherwise be caused by airflow across the grid surface.

Along the top inside edge, evenly disposed along the full length of each lens support (50) are lens retainers (49) fastened to the lens supports (50) by screws. Each lens retainer (49) has a grove sized to receive the edge of the Fresnel lens (43) similar to a tongue and grove fitting to hold the lens firmly in position. The lens retainers (49) are fabricated either from a hard rubberized material or plastic. Each short side of each Fresnel lens (43) is secured to the lens retainers (49) in this manner. The length of each lens retainers (49) matches the length of each Fresnel lens (43) short side dimension.

As shown in the panel Section A-A, the Solar Collector Panel (40) is constructed as a sandwich of component layers. The first layer is the glass/plastic cover plate (46) held in place by the overlaying lip formed on the top of the frame (42) side members. In the preferred embodiment the cover plate (46) is made from glass but it can be plastic. Mounted below the cover plate (46) is the photovoltaic (PV) grid (41). A copper sheet (47) is mated between the Photovoltaic (PV) grid (41) substrate and the copper tubing heat exchanger (48) to uniformly absorb incoming heat from the Sun and distribute it to the copper tubing heat exchanger (48). Similarly, the copper sheet (47) uniformly distributes heat from the copper tubing heat exchanger (48) to the Photovoltaic (PV) grid (41) substrate for radiation to the atmosphere when the Solar Collector Panel (40) is connected for heat dissipation. For maximum heat transfer, the copper tubing heat exchanger (48) is bonded to the heat transfer copper sheet (47) using a thermal conducting compound. In the preferred embodiment, the compound is a copper-filled epoxy. Foam insulation (51) lies between the copper tubing heat exchanger (48) and the bottom cover plate (52) to reduce heat leakage from the Solar Collector Panel (40), retaining maximum heat for transfer to or from the user plant. Rivets secure the bottom cover plate (52) so that the entire collector panel sandwich is firmly held in place.

The anodized aluminum frame (42) has attached to the bottom of the frame along the length of a first long side and a second long side, an L-shaped aluminum channel with mounting holes disposed evenly across the length of the channel. These mounting holes allow for the fastening of the collector panel frame to the embedment (30) described below.

The improvement to the above design is the addition of a first waterproof, self-sealing, membrane (15) with a top surface and an opposed bottom surface that has a first adhesive layer (14) applied to its top surface. The first waterproof, self-sealing, membrane (15) is secured to the bottom cover plate (52) by the first adhesive layer. These layers form the interface to the embedment (30) whose several embodiments are described below.

The embedment, which is also part of the improvement, is constructed as a sandwich of layers. In one embodiment, the bottom layer is standard building construction material (22) as used for roof or deck sheathing. This material may be made from wood products graded for exterior construction or solid insulation board with a top surface and an opposed bottom surface. A second waterproof, self-sealing, membrane (20) with a top surface and an opposed bottom surface has a second adhesive layer (21) applied to the opposed bottom surface. The opposed bottom surface of the second waterproof, self-sealing, membrane (20) is secured to the building construction material (22) top surface by the second adhesive layer.

A solid insulation board (19) with a top surface and an opposed bottom surface, whose thickness is selected to satisfy applicable local building codes when required, is placed on the top surface of the membrane (20), with its bottom surface facing down. A second lap cement layer (18) is applied to the exposed top surface of the solid insulation board (19).

A fiberglass and asphalt based sheathing (17) with a top surface and an opposed bottom surface is directly applied, with its bottom surface facing down, to the second lap cement layer (18) while the lap cement is still wet.

A first lap cement layer (16) is applied to the top surface of the fiberglass and asphalt based sheathing (17) and then the Solar Panel (1) is seated on the first lap cement layer (16) and secured with stainless steel attaching screws (77).

In a second embodiment of the embedment, the bottom layer is formed by standard building construction material (22) as used for roof or deck sheathing. This material may be made from wood products graded for exterior construction or solid insulation board with a top surface and a bottom surface. A second waterproof, self-sealing, membrane (20) with a top surface and an opposed bottom surface has a second adhesive layer (21) applied to the opposed bottom surface. The opposed bottom surface of the second waterproof, self-sealing, membrane (20) is secured to the building construction material (22) top surface by the adhesive layer. A second lap cement layer (18) is applied to the exposed top surface of the second waterproof, self-sealing, membrane (20).

A fiberglass and asphalt based sheathing (17) with a top surface and an opposed bottom surface is directly applied, with its bottom surface facing down, to the second lap cement layer (18) while the lap cement is still wet.

A first lap cement layer (16) is applied to the top surface of the fiberglass and asphalt based sheathing (17) and then the Solar Panel (1) is seated on the first lap cement layer (16) and secured with stainless steel attaching screws (77).

Alternate improvement embodiments to those described above involve replacement of the copper tubing heat exchanger (9), (48) with an aluminum tubing heat exchanger or an aluminum or copper, thin-profile water tank.

A general installation method has been developed for interfacing the described embodiments of the solar collector panel (1) and the solar collector panel with Fresnel Lenses (40). Each embodiment of the collector panel is assembled at the factory with the added layers of the first waterproof, self-sealing, membrane (15) with a first adhesive layer (14) applied to the membrane's top surface and then adhesively secured to the bottom cover plate (52) or the aluminum bottom plate (10) by the adhesive layer.

The embedments are also partially prefabricated at the factory. These assemblies include the roof or deck sheathing (22) covered with second waterproof, self-sealing membrane (20) that is attached to the sheathing by the second adhesive layer (21).

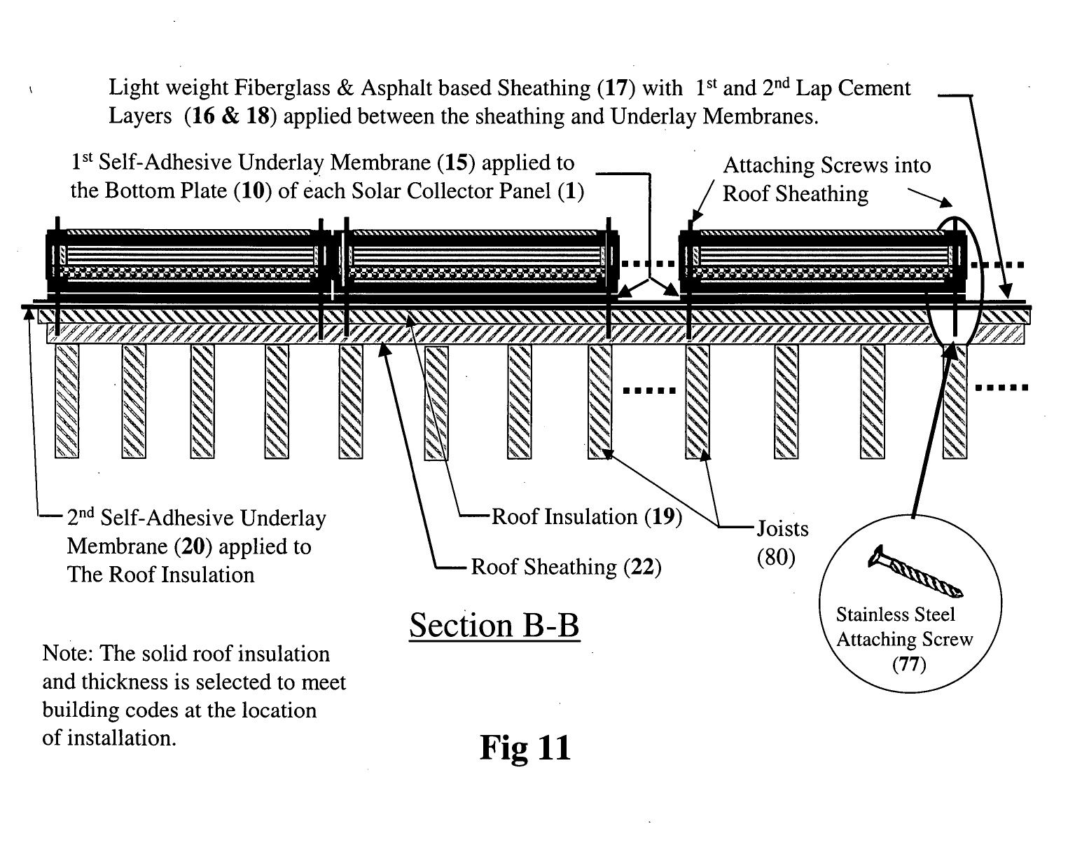

In the field, this embedment is attached to roof joists by standard construction fastening means that includes nails, screws, or bolts. As shown in FIG. 10, after the embedment is attached to the roof joists, the second lap cement layer (18) is applied by roller or brush to the second waterproof, self-sealing membrane (20). Then the light weight fiberglass and Asphalt based sheathing (17) is applied to the wet lap cement layer (18) and the first lap cement layer (16) is applied to the exposed top surface of the light weight fiberglass and Asphalt based sheathing (17). The solar panel (1) or (40) is emplaced on the embedment and firmly attached by stainless steel attaching screws (77).

Where required by local building insulation codes, the method is modified with the addition of insulation board as shown in FIG. 11. After the embedment is attached to the roof sheathing, a solid insulation board (19) whose thickness is determined by the local building codes is laid upon the top surface of the second self-sealing membrane (20) with its opposed bottom surface facing down. Then the second lap cement layer (18) is applied by roller or brush to the exposed top surface of the solid insulation board (19). Then the light weight fiberglass and Asphalt based sheathing (17) is applied to the wet lap cement layer (18) with its opposed bottom surface facing down. Then the first lap cement layer (16) is applied to the exposed top surface of the lightweight fiberglass and Asphalt based sheathing (17). The solar panel (1) or (40) is emplaced on the embedment while the first lap cement layer is still wet and firmly attached by stainless steel attaching screws (77).

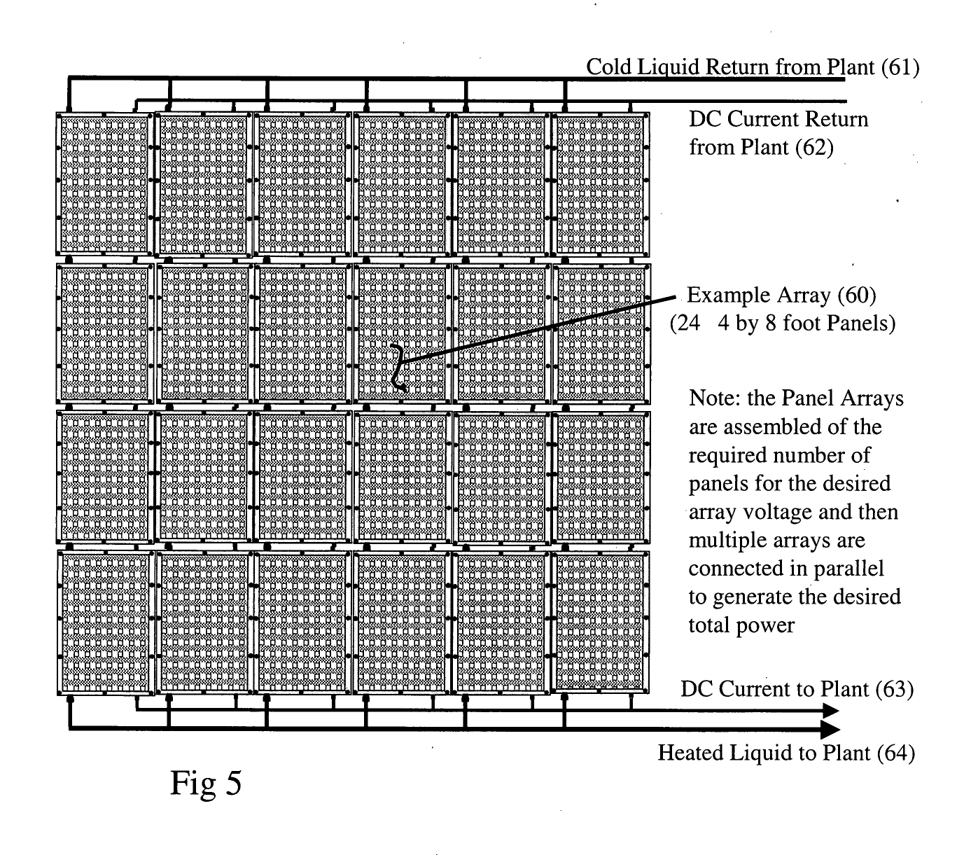

As shown in FIG. 5 the solar Collector panel (1) or (40) can be arranged in various series parallel arrays by external connections of liquid plumbing and electrical connections. FIG. 5 shows an example array (60) of 24 such interconnected panels. The arrays are assembled to attain the desired array voltage and then multiple arrays are connected in parallel to generate the desired current. Typically, solar collector panels arrays (60) are integrated within a system to provide a heated liquid for a building liquid system and simultaneously provide electrical power for a building electrical system by providing Heated liquid to the users plant (64) and DC current to the plant (63) and drawing cold liquid return (61) and DC current return (62) from the plant.

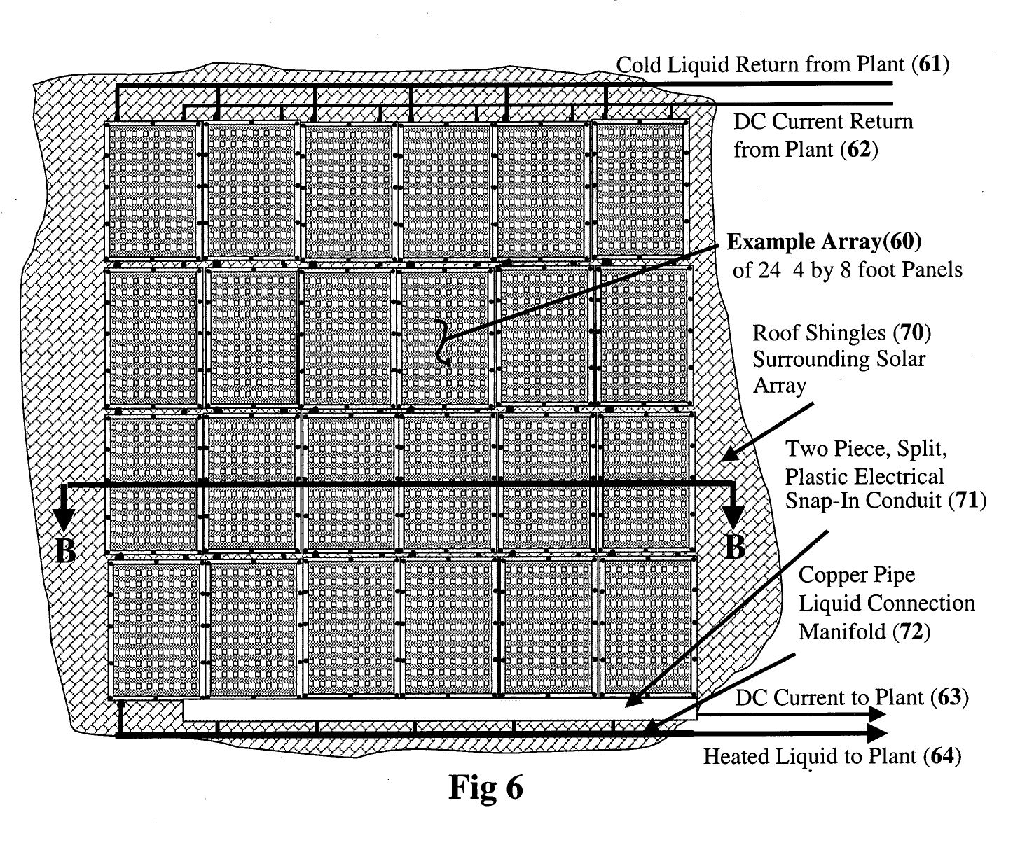

Further shown in FIG. 6, the array (60) may be surrounded by roofing shingles (70).

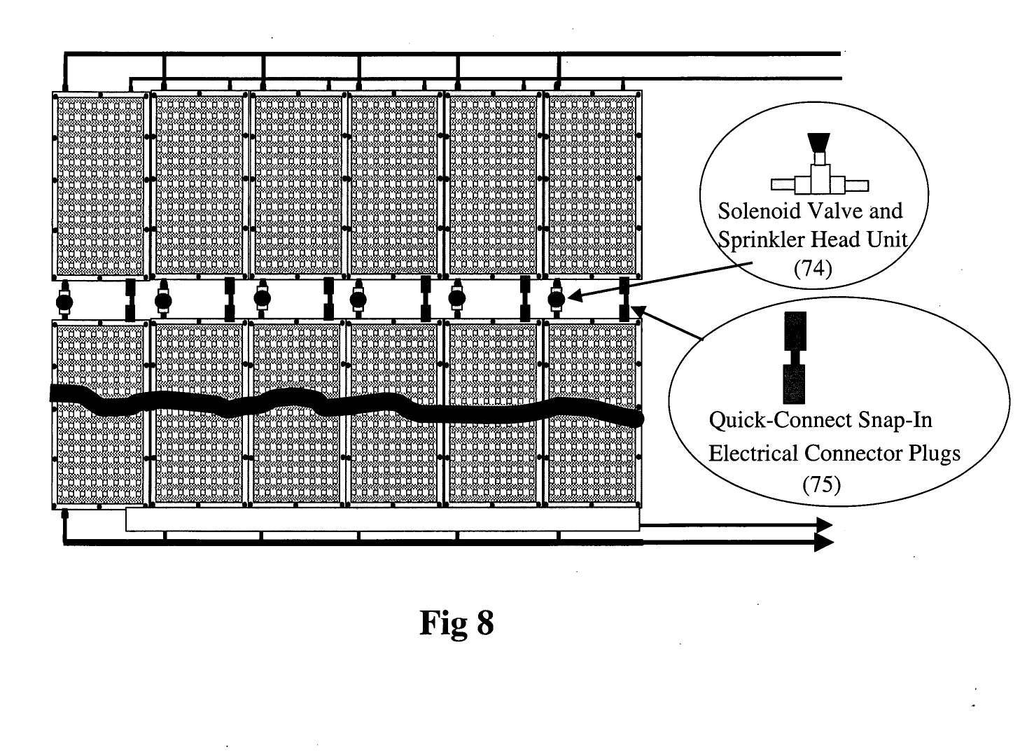

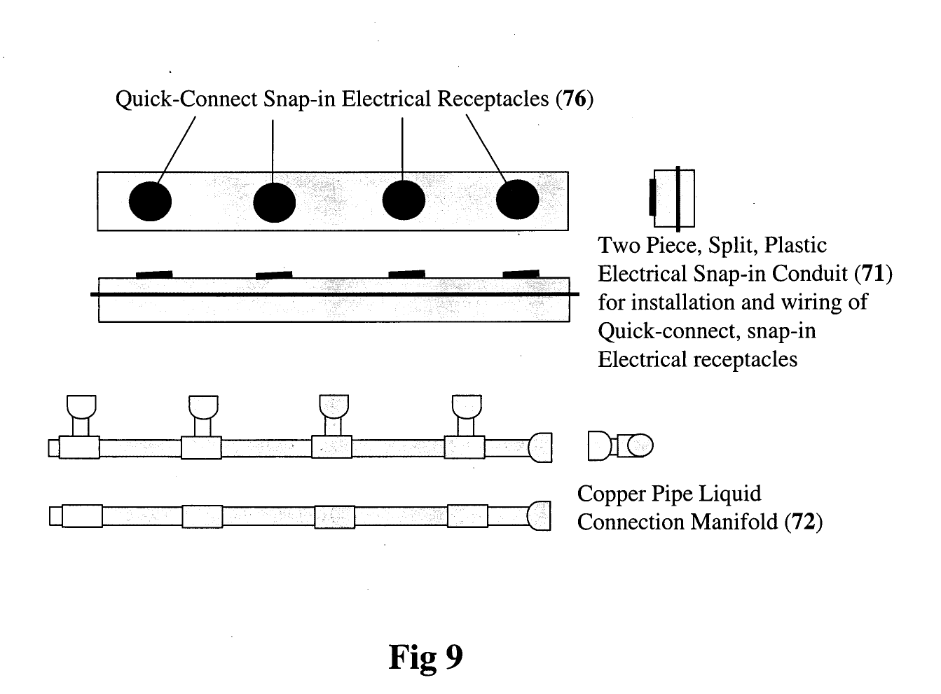

Each panel's liquid discharge is connected to the next series connected panel inlet by copper quick connect fittings and finally collected within the array by a copper pipe liquid connection manifold (72) which is shown in greater details in FIGS. 6 and 9. Similarly, electrical connections between panels are made by quick-connect snap-in electrical connector plugs (75) and receptacles (76) as shown in FIGS. 8 and 9.

DC current is routed from the solar panels to the solar system by a raceway (71) and high temperature 12 gauge cabling rated at 200° C. As illustrated in FIGS. 8 and 9, DC current is captured from the end panels of each photovoltaic panel (1) string through the raceway (71) using of quick-connect snap-in electrical connector plugs (75) and receptacles (76). The electrical connection raceway is a two-piece, split, plastic assembly retaining the snap-in receptacles (76) as shown in FIGS. 6 and 9. The raceway is split to permit interconnection of the receptacles (76). Finally, DC current is routed from the raceway to the solar system through weather-tight, plastic covered conduit. Signal cabling from the discharge temperature sensors (109) is also brought through the conduit in the same manner, with a separate circuit for each sensor.

For fire suppression, solar panel cleaning, and roof cooling applications, an optional solenoid valve and sprinkler head unit (74) is connected between panels. The solenoid valves are controlled by the liquid discharge temperature sensor (109), which is set to detect temperatures in advance of a fire danger and saturate the roof with water. The valves (74) are similarly controlled for panel cleaning and roof cooling through a controller device (110) to trigger the solenoid valve and sprinkler head unit (74).

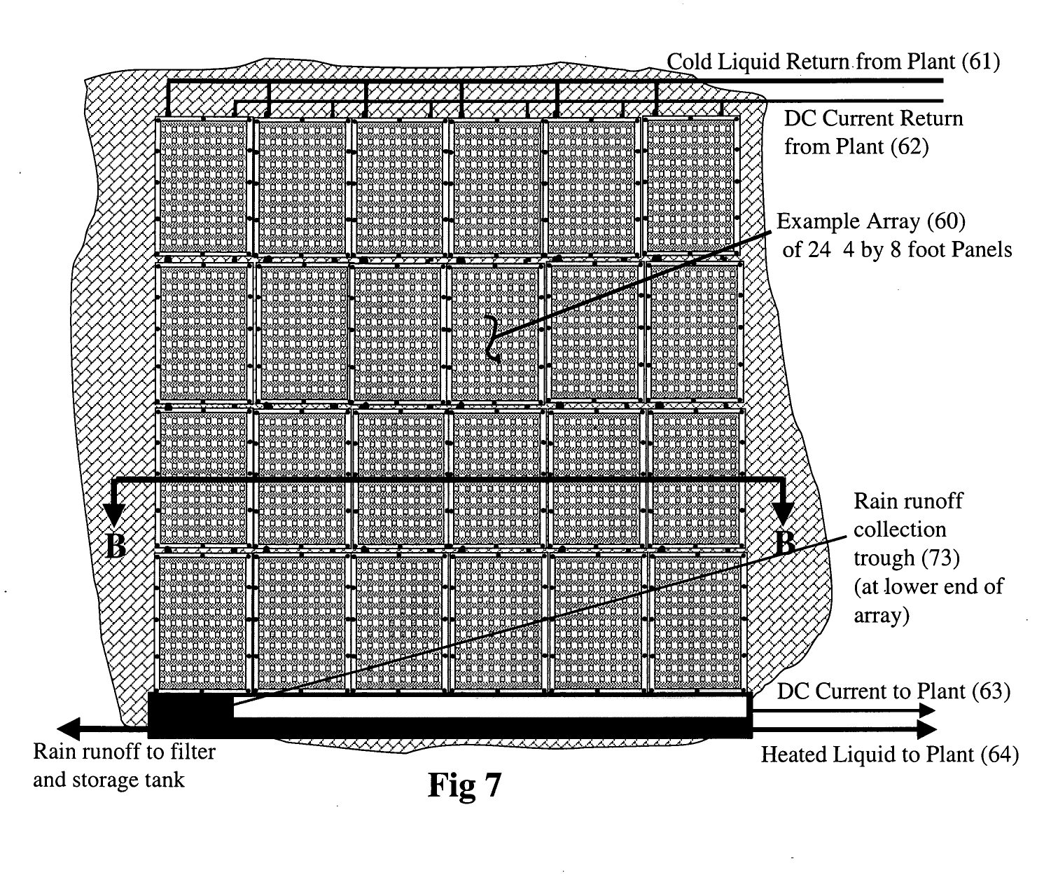

Another options provided in this design, as shown in FIG. 7, is a rain runoff collection trough (73) fastened at the lower end of the array to collect rain water and direct it to a filter and rooftop storage tank (105) arrangement as described. This trough (73) is also used to collect run-off water during panel cleaning and roof cooling.

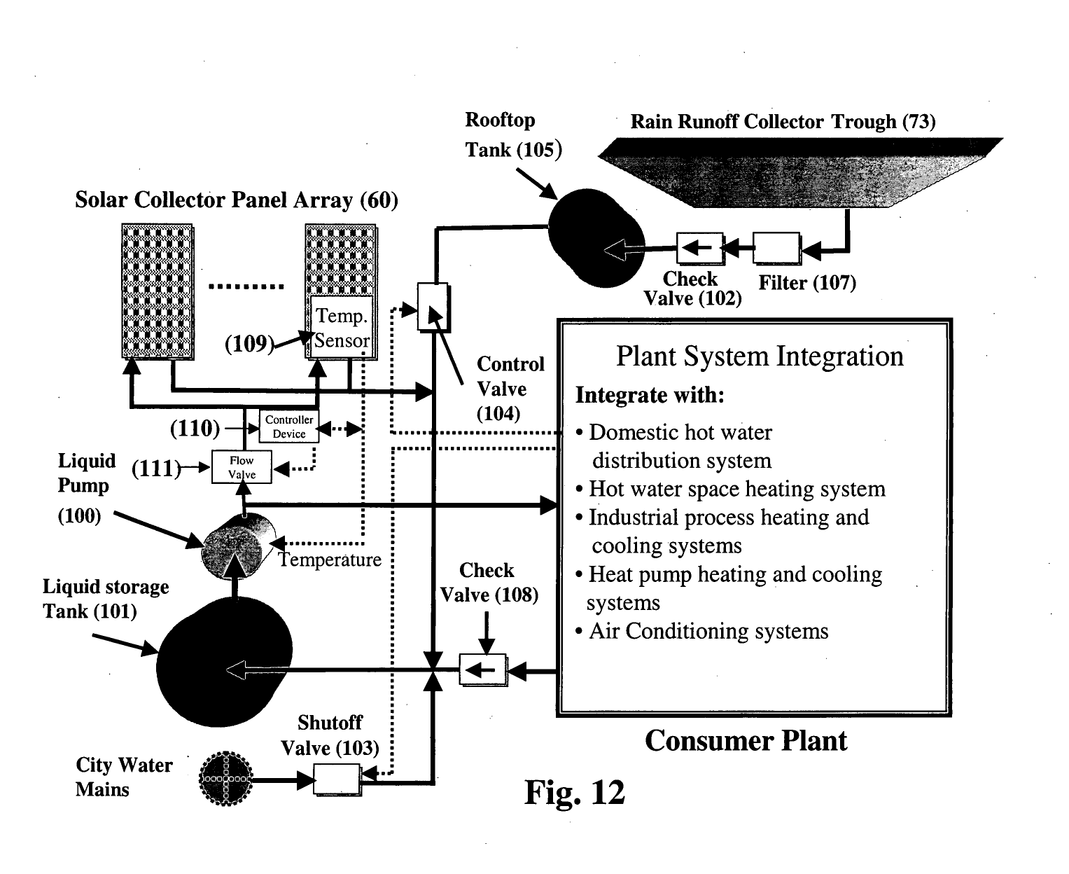

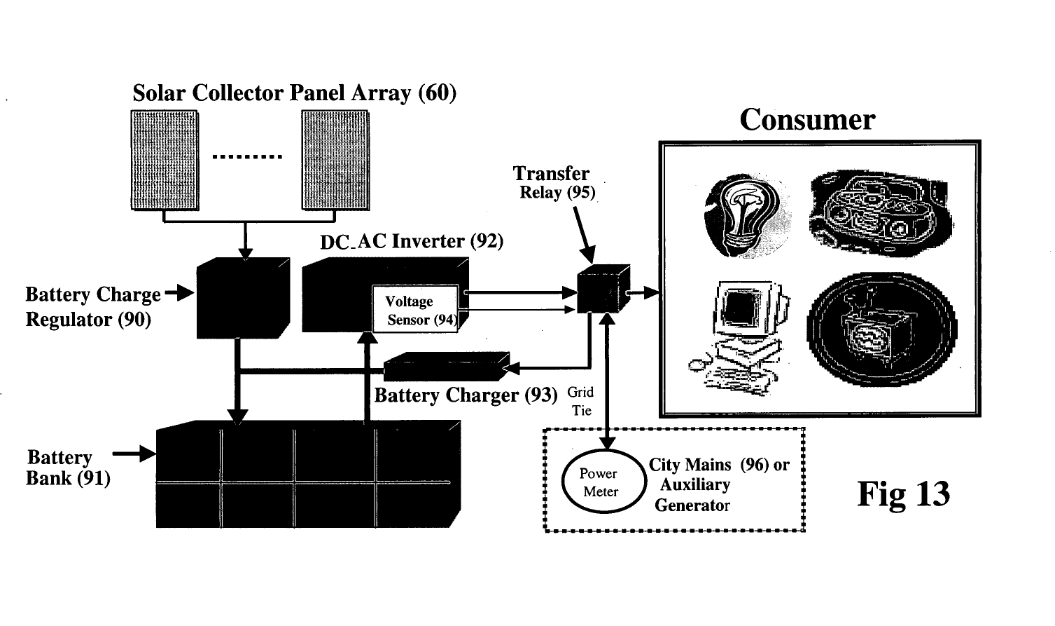

As described in U.S. Pat. No. 6,630,622, which is incorporated by reference, solar collector panels are typically integrated within a system to provide a heated liquid for a building liquid system and simultaneously provide electrical power for a building electrical system. A photovoltaic unit portion of a panel has its electrical output connected to a battery charge regulator (90) which charges a battery bank (91) which, in turn, drives a DC to AC inverter (92) providing useful AC electrical power that is fed into the building electrical system. There are numerous variations of this arrangement that are well understood in the art. Typical Solar systems that can incorporate this Solar panel and any of its configurations are illustrated in FIG. 12 for the liquid heat transfer application and FIG. 13 for the electrical power application.

In general, battery charge regulators (90) keep the battery bank charged, prevent overcharging, and regulate electric current flow from the photovoltaic grid (1), (40) to the battery bank (91). Battery output current is supplied to one or more DC to AC inverters (92) to convert DC battery power to AC power to supply power at the required voltage and frequency to operate consumer electrical apparatus. A battery voltage sensor (94) may be provided to determine when the solar array power is not sufficient to keep the battery bank (91) fully charged to satisfy consumer power demand, at which time it activates a transfer relay (95) to connect the battery charger (93) to city mains (96) or a consumer auxiliary generator for additional power. The consumer can be provided with additional control of the transfer relay (95) to direct city mains power to his plant and/or feed unused solar power from the DC to AC Inverter (92) back to the city utility grid.

The solar panel liquid discharge is connected to a closed liquid loop pressurized by a liquid pump (100) that pumps the heated liquid into liquid storage tanks (101) and then out to the building liquid system for heated liquid fluid use, returning cooler liquid to a liquid input of the panel There are also numerous variations of this arrangement that are well understood in the art.

Cold liquid flows from a consumer's plant into the panels and heated liquid flows out of the panels into the consumer's plant. An array of the Collector Panels (60) may be integrated with consumer plant systems such as an Air Conditioning or a heat pump system to add or remove heat, thus replacing or augmenting the heat transfer components of these systems.

Controlling fluid flow in consumer plant heat transfer systems is generally understood in the art. Check valves (102) provide liquid flow in a single direction to prevent the flow directly from the source into the consumer plant. A shutoff valve (103) can be provided for consumer control of incoming liquid. A control valve (104) is often provided for consumer control of liquid flow to and from storage tanks, such as rooftop tanks (105) combined with a rain runoff collection trough (73), a filter (107), and a check valve (108). The rooftop tank (105) provides plant liquid pressurization in the absence of other sources of pressurization, such as city water.

In a cold climate, a liquid is cooled for industrial processes or machines such as a stationery engine. Hot liquid flows from a consumer's plant into the panels and cooled liquid flows out of the panels into the consumer's plant. A rooftop may be heated through the Collector Panels to reduce snow and ice build-up, and keep the Collector Panels free of snow and ice.

Depending upon the climate where the Collector Panel array (60) is installed, heat is removed from or added to the Panels improving their Photovoltaic efficiency, minimizing thermal stress and material deterioration to yield maximum lifetime, and providing a cooled or heated liquid for the consumer at the same time. Consumer plant liquid flow and temperature control and thermal energy storage or dissipation is provided through a temperature sensor (109) included as part of the Collector Panel (1), (40). The sensor is an integral part of the Collector Panel (1), (40) for domestic, industrial, and commercial system/process controls. The sensor analog output signal can be interfaced to a controller device (110) which can be a process control microprocessor, programmable controller, or Proportional-Integral-Derivative (PID) 3-mode controller whose output controls a proportional flow control valve (111) to control liquid flow as a function of collector panel discharge flow temperature. The Panel photovoltaic grid temperature is thus maintained within an optimal operating range of 70 to 100 degrees F. Additionally, the sensor (109) analog output signal and the controller device (110) analog output signal can also interface with a pump (100) that pumps the liquid through the liquid flow closed loop.

1. An improved solar collector panel for thermal radiant cooling and for simultaneously converting solar energy to electrical power and thermal energy comprising: a rectangular frame with an open top side and a bottom side closed by an aluminum bottom plate; a photovoltaic grid for converting solar energy transmitted into the collector into electrical energy; a thermal collecting/radiator sheet, located on a plane below the photovoltaic grid, for converting solar energy transmitted into the collector into thermal energy; a copper tubing heat exchanger containing a plurality of interconnected heat collecting copper tubes disposed on a plane below the thermal collecting/radiator sheet but conductively coupled to the sheet through a thermally conductive material that collects thermal energy from the sheet and imparts that thermal energy in a fluid disposed within the heat collecting copper tubes; wherein the improvement comprises:
(a) a first waterproof, self-sealing, membrane with a top surface and an opposed bottom surface;
(b) a first adhesive layer in contact with the top surface of the first self-sealing, membrane forming an interface that is adhesively secured to the aluminum bottom plate of the collector by the first adhesive layer;
(c) mounting screw guide tubes that extend the entire depth of the collector panel from the top of the frame through the aluminum bottom plate evenly disposed around each side of the collector frame for securing the panel to the embedment with fasteners;
(d) a separate embedment component that includes:
a. a bottom layer made from standard building construction material as used for roof or deck sheathing with a top surface and an opposed bottom surface;
b. a second waterproof, self-sealing, membrane with a top surface and an opposed bottom surface;
c. a second adhesive layer in contact with the opposed bottom surface of the second waterproof, self-sealing, membrane that adhesively secures it to the building construction material top surface;
d. a solid insulation board with a top surface and an opposed bottom surface, whose thickness is selected to satisfy applicable local building codes when required, placed with opposed bottom surface in contact with the top surface of the second waterproof, self-sealing, membrane;
e. a second lap cement layer in contact with the exposed top surface of the solid insulation board;
f. a fiberglass and asphalt based sheathing with a top surface and an opposed bottom surface adhesively applied, opposed bottom surface down, to the second lap cement layer; and
g. a first lap cement layer in contact with the top surface of the fiberglass and asphalt based sheathing for receiving and adhesively securing the collector panel by its first waterproof, self-sealing, membrane opposed bottom surface and secondly secured with fasteners placed through the mounting screw guide tubes.
(e) copper quick connect fittings attached to the liquid inlet and outlet of each panel;
(f) copper pipe liquid connection manifolds for liquid distribution to and collection from panels arrays that are connected to the manifold by the copper quick connect fittings;
(g) a plastic raceway placed to receive electrical wiring from each panel or series panel string arranged in an array;
(h) quick-connect snap-in electrical connector plugs for the electrical interconnection of panels;
(i) quick-connect snap-in electrical connector receptacles to connect panels or series strings of panels to the raceway;
(j) a rain runoff collection trough connected to the lowest end of a slanted roof mounted solar panel or array of solar panels;
(k) solenoid valves and sprinkler head units connected between rows of panels that receive on/off control signals through their connected wiring; and
(l) an improved heat exchanger selected from the group consisting of: aluminum tubing heat exchanger; copper, thin-profile, water tank and aluminum, thin-profile, water tank.

2. The improved solar collector panel of claim 1 wherein the standard building construction material is exterior grade wood sheathing.

3. The improved solar collector panel of claim 1 wherein the fasteners are stainless steel screws.

4. The improved solar collector panel of claim 1 wherein the solenoid valve and sprinkler head units on/off control signal originates from a controller device whose input analog temperature signal originates from each solar panel internal temperature sensor.

5. An improved solar collector panel for thermal radiant cooling and for simultaneously converting solar energy to electrical power and thermal energy comprising: a rectangular frame with an open top side and a bottom side closed by an aluminum bottom plate; a photovoltaic grid for converting solar energy transmitted into the collector into electrical energy; a thermal collecting/radiator sheet, located on a plane below the photovoltaic grid, for converting solar energy transmitted into the collector into thermal energy; a copper tubing heat exchanger containing a plurality of interconnected heat collecting copper tubes disposed on a plane below the thermal collecting/radiator sheet but conductively coupled to the sheet through a thermally conductive material that collects thermal energy from the sheet and imparts that thermal energy in a fluid disposed within the heat collecting copper tubes; wherein the improvement comprises:
(a) a first waterproof, self-sealing, membrane with a top surface and an opposed bottom surface;
(b) a first adhesive layer in contact with the top surface of the first self-sealing, membrane forming an interface that is adhesively secured to the aluminum bottom plate of the collector by the first adhesive layer;
(c) mounting screw guide tubes that extend the entire depth of the collector panel from the top of the frame through the aluminum bottom plate evenly disposed around each side of the collector frame;
(d) a separate embedment component that includes:
a. a bottom layer made from standard building construction material as used for roof or deck sheathing with a top surface and an opposed bottom surface;
b. a second waterproof, self-sealing, membrane with a top surface and an opposed bottom surface;
c. a second adhesive layer in contact with the opposed bottom surface of the second waterproof, self-sealing, membrane that adhesively secures it to the building construction material top surface;
d. a second lap cement layer in contact with the exposed top surface of the second waterproof, self-sealing, membrane;
e. a fiberglass and asphalt based sheathing with a top surface and an opposed bottom surface adhesively applied, opposed bottom surface down, to the second lap cement layer; and
f. a first lap cement layer in contact with the top surface of the fiberglass and asphalt based sheathing for receiving and adhesively securing the collector panel by its first waterproof, self-sealing, membrane opposed bottom surface and secondly secured with fasteners placed through the mounting screw guide tubes.
(e) copper quick connect fittings attached to the liquid inlet and outlet of each panel;
(f) copper pipe liquid connection manifolds for liquid distribution to and collection from panels arrays that are connected to the manifold by the copper quick connect fittings;
(g) a plastic raceway placed to receive electrical wiring from each panel or series panel string arranged in an array;
(h) quick-connect snap-in electrical connector plugs for the electrical interconnection of panels;
(i) quick-connect snap-in electrical connector receptacles to connect panels or series strings of panels to the raceway;
(j) a rain runoff collection trough connected to the lowest end of a slanted roof mounted solar panel or array of solar panels;
(k) solenoid valves and sprinkler head units connected between rows of panels that receive on/off control signals through their connected wiring; and
(l) an improved heat exchanger selected from the group consisting of: aluminum tubing heat exchanger; copper, thin-profile, water tank and aluminum, thin-profile, water tank.

6. The improved solar collector panel of claim 5 wherein the standard building construction material is exterior grade wood sheathing.

7. The improved solar collector panel of claim 5 wherein the fasteners are stainless steel screws.

8. The improved solar collector panel of claim 5 wherein the solenoid valve and sprinkler head units on/off control signal originates from a controller device whose input analog temperature signal originates from each solar panel internal temperature sensor.

9. An improved solar collector panel for thermal radiant cooling and for simultaneously converting solar energy to electrical power and thermal energy comprising: a rectangular frame with an open top side and a bottom side closed by an aluminum bottom plate; a thin-film photovoltaic grid vacuum deposited on a clear vinyl substrate for converting solar energy transmitted into the collector into electrical energy; a thermal collecting/radiator sheet, located on a plane below the thin-film photovoltaic grid, for converting solar energy transmitted into the collector into thermal energy; a copper tubing heat exchanger containing a plurality of interconnected heat collecting copper tubes disposed on a plane below the thermal collecting/radiator sheet but conductively coupled to the sheet through a thermally conductive material that collects thermal energy from the sheet and imparts that thermal energy in a fluid disposed within the heat collecting copper tubes; wherein the improvement comprises:
(a) a first waterproof, self-sealing, membrane with a top surface and an opposed bottom surface;
(b) a first adhesive layer in contact with the top surface of the first self-sealing, membrane forming an interface that is adhesively secured to the aluminum bottom plate of the collector by the first adhesive layer;
(c) mounting screw guide tubes that extend the entire depth of the collector panel from the top of the frame through the aluminum bottom plate evenly disposed around each side of the collector frame;
(d) a separate embedment component that includes:
a. a bottom layer made from standard building construction material as used for roof or deck sheathing with a top surface and an opposed bottom surface;
b. a second waterproof, self-sealing, membrane with a top surface and an opposed bottom surface;
c. a second adhesive layer in contact with the opposed bottom surface of the second waterproof, self-sealing, membrane that adhesively secures it to the building construction material top surface;
d. a solid insulation board with a top surface and an opposed bottom surface, whose thickness is selected to satisfy applicable local building codes when required, placed with opposed bottom surface in contact with the top surface of the second waterproof, self-sealing, membrane;
e. a second lap cement layer in contact with the exposed top surface of the solid insulation board;
f. a fiberglass and asphalt based sheathing with a top surface and an opposed bottom surface adhesively applied, opposed bottom surface down, to the second lap cement layer; and
g. a first lap cement layer in contact with the top surface of the fiberglass and asphalt based sheathing for receiving and adhesively securing the collector panel by its first waterproof, self-sealing, membrane opposed bottom surface and secondly secured with fasteners placed through the mounting screw guide tubes.
(e) copper quick connect fittings attached to the liquid inlet and outlet of each panel;
(f) copper pipe liquid connection manifolds for liquid distribution to and collection from panels arrays that are connected to the manifold by the copper quick connect fittings;
(g) a plastic raceway placed to receive electrical wiring from each panel or series panel string arranged in an array;
(h) quick-connect snap-in electrical connector plugs for the electrical interconnection of panels;
(i) quick-connect snap-in electrical connector receptacles to connect panels or series strings of panels to the raceway;
(j) a rain runoff collection trough connected to the lowest end of a slanted roof mounted solar panel or array of solar panels;
(k) solenoid valves and sprinkler head units connected between rows of panels that receive on/off control signals through their connected wiring; and
(l) an improved heat exchanger selected from the group consisting of: aluminum tubing heat exchanger; copper, thin-profile, water tank and aluminum, thin-profile, water tank.

10. The improved solar collector panel of claim 9 wherein the standard building construction material is exterior grade wood sheathing.

11. The improved solar collector panel of claim 9 wherein the fasteners are stainless steel screws.

12. The improved solar collector panel of claim 9 wherein the solenoid valve and sprinkler head units on/off control signal originates from a controller device whose input analog temperature signal originates from each solar panel internal temperature sensor.

13. An improved solar collector panel for thermal radiant cooling and for simultaneously converting solar energy to electrical power and thermal energy comprising: a rectangular frame with an open top side and a bottom side closed by an aluminum bottom plate; a thin-film photovoltaic grid vacuum deposited on a clear vinyl substrate for converting solar energy transmitted into the collector into electrical energy; a thermal collecting/radiator sheet, located on a plane below the photovoltaic grid, for converting solar energy transmitted into the collector into thermal energy; a copper tubing heat exchanger containing a plurality of interconnected heat collecting copper tubes disposed on a plane below the thermal collecting/radiator sheet but conductively coupled to the sheet through a thermally conductive material that collects thermal energy from the sheet and imparts that thermal energy in a fluid disposed within the heat collecting copper tubes; wherein the improvement comprises:
(a) a first waterproof, self-sealing, membrane with a top surface and an opposed bottom surface;
(b) a first adhesive layer in contact with the top surface of the first self-sealing, membrane forming an interface that is adhesively secured to the aluminum bottom plate of the collector by the first adhesive layer;
(c) mounting screw guide tubes that extend the entire depth of the collector panel from the top of the frame through the aluminum bottom plate evenly disposed around each side of the collector frame;
(d) a separate embedment component that includes:
a. a bottom layer made from standard building construction material as used for roof or deck sheathing with a top surface and an opposed bottom surface;
b. a second waterproof, self-sealing, membrane with a top surface and an opposed bottom surface;
c. a second adhesive layer in contact with the opposed bottom surface of the second waterproof, self-sealing, membrane that adhesively secures it to the building construction material top surface;
d. a second lap cement layer in contact with the exposed top surface of the second waterproof, self-sealing, membrane;
e. a fiberglass and asphalt based sheathing with a top surface and an opposed bottom surface adhesively applied, opposed bottom surface down, to the second lap cement layer; and
f. a first lap cement layer in contact with the top surface of the fiberglass and asphalt based sheathing for receiving and adhesively securing the collector panel by its first waterproof, self-sealing, membrane opposed bottom surface and secondly secured with fasteners placed through the mounting screw guide tubes.
(e) copper quick connect fittings attached to the liquid inlet and outlet of each panel;
(f) copper pipe liquid connection manifolds for liquid distribution to and collection from panels arrays that are connected to the manifold by the copper quick connect fittings;
(g) a plastic raceway placed to receive electrical wiring from each panel or series panel string arranged in an array;
(h) quick-connect snap-in electrical connector plugs for the electrical interconnection of panels;
(i) quick-connect snap-in electrical connector receptacles to connect panels or series strings of panels to the raceway;
(j) a rain runoff collection trough connected to the lowest end of a slanted roof mounted solar panel or array of solar panels;
(k) solenoid valves and sprinkler head units connected between rows of panels that receive on/off control signals through their connected wiring; and
(l) an improved heat exchanger selected from the group consisting of: aluminum tubing heat exchanger; copper, thin-profile, water tank and aluminum, thin-profile, water tank.

14. The improved solar collector panel of claim 13 wherein the standard building construction material is exterior grade wood sheathing.

15. The improved solar collector panel of claim 13 wherein the fasteners are stainless steel screws.

16. The improved solar collector panel of claim 13 wherein the solenoid valve and sprinkler head units on/off control signal originates from a controller device whose input analog temperature signal originates from each solar panel internal temperature sensor.

17. An improved solar collector panel for thermal radiant cooling and for simultaneously converting solar energy to electrical power and thermal energy comprising: a rectangular frame with an open top side and a bottom side closed by an aluminum bottom plate; lens supports secured to the frame sides supporting Fresnel lenses that provide a passive solar tracking function; a photovoltaic grid for converting solar energy transmitted into the collector into electrical energy; a thermal collecting/radiator sheet, located on a plane below the photovoltaic grid, for converting solar energy transmitted into the collector into thermal energy; a copper tubing heat exchanger containing a plurality of interconnected heat collecting copper tubes disposed on a plane below the thermal collecting/radiator sheet but conductively coupled to the sheet through a thermally conductive material that collects thermal energy from the sheet and imparts that thermal energy in a fluid disposed within the heat collecting copper tubes; wherein the improvement comprises:
(a) a first waterproof, self-sealing, membrane with a top surface and an opposed bottom surface;
(b) a first adhesive layer in contact with the top surface of the first self-sealing, membrane forming an interface that is adhesively secured to the aluminum bottom plate of the collector by the first adhesive layer;
(c) mounting screw guide tubes that extend the entire depth of the collector panel from the top of the frame through the aluminum bottom plate evenly disposed around each side of the collector frame;
(d) a separate embedment component that includes:
a. a bottom layer made from standard building construction material as used for roof or deck sheathing with a top surface and an opposed bottom surface;
b. a second waterproof, self-sealing, membrane with a top surface and an opposed bottom surface;
c. a second adhesive layer in contact with the opposed bottom surface of the second waterproof, self-sealing, membrane that adhesively secures it to the building construction material top surface;
d. a solid insulation board with a top surface and an opposed bottom surface, whose thickness is selected to satisfy applicable local building codes when required, placed with opposed bottom surface in contact with the top surface of the second waterproof, self-sealing, membrane;
e. a second lap cement layer in contact with the exposed top surface of the solid insulation board;
f. a fiberglass and asphalt based sheathing with a top surface and an opposed bottom surface adhesively applied, opposed bottom surface down, to the second lap cement layer; and
g. a first lap cement layer in contact with the top surface of the fiberglass and asphalt based sheathing for receiving and adhesively securing the collector panel by its first waterproof, self-sealing, membrane opposed bottom surface and secondly secured with fasteners placed through the mounting screw guide tubes.
(e) copper quick connect fittings attached to the liquid inlet and outlet of each panel;
(f) copper pipe liquid connection manifolds for liquid distribution to and collection from panels arrays that are connected to the manifold by the copper quick connect fittings;
(g) a plastic raceway placed to receive electrical wiring from each panel or series panel string arranged in an array;
(h) quick-connect snap-in electrical connector plugs for the electrical interconnection of panels;
(i) quick-connect snap-in electrical connector receptacles to connect panels or series strings of panels to the raceway;
(j) a rain runoff collection trough connected to the lowest end of a slanted roof mounted solar panel or array of solar panels;
(k) solenoid valves and sprinkler head units connected between rows of panels that receive on/off control signals through their connected wiring; and
(k) an improved heat exchanger selected from the group consisting of: aluminum tubing heat exchanger; copper, thin-profile, water tank and aluminum, thin-profile, water tank.

18. The improved solar collector panel of claim 17 wherein the standard building construction material is exterior grade wood sheathing.

19. The improved solar collector panel of claim 17wherein the fasteners are stainless steel screws.

20. The improved solar collector panel of claim 17 wherein the solenoid valve and sprinkler head units on/off control signal originates from a controller device whose input analog temperature signal originates from each solar panel internal temperature sensor.

21. An improved solar collector panel for thermal radiant cooling and for simultaneously converting solar energy to electrical power and thermal energy comprising: a rectangular frame with an open top side and a bottom side closed by an aluminum bottom plate; lens supports secured to the frame sides supporting Fresnel lenses that provide a passive solar tracking function; a photovoltaic grid for converting solar energy transmitted into the collector into electrical energy; a thermal collecting/radiator sheet, located on a plane below the photovoltaic grid, for converting solar energy transmitted into the collector into thermal energy; a copper tubing heat exchanger containing a plurality of interconnected heat collecting copper tubes disposed on a plane below the thermal collecting/radiator sheet but conductively coupled to the sheet through a thermally conductive material that collects thermal energy from the sheet and imparts that thermal energy in a fluid disposed within the heat collecting copper tubes; wherein the improvement comprises:
(a) a first waterproof, self-sealing, membrane with a top surface and an opposed bottom surface;
(b) a first adhesive layer in contact with the top surface of the first self-sealing, membrane forming an interface that is adhesively secured to the aluminum bottom plate of the collector by the first adhesive layer;
(c) mounting screw guide tubes that extend the entire depth of the collector panel from the top of the frame through the aluminum bottom plate evenly disposed around each side of the collector frame;
(d) a separate embedment component that includes:
a. a bottom layer made from standard building construction material as used for roof or deck sheathing with a top surface and an opposed bottom surface;
b. a second waterproof, self-sealing, membrane with a top surface and an opposed bottom surface;
c. a second adhesive layer in contact with the opposed bottom surface of the second waterproof, self-sealing, membrane that adhesively secures it to the building construction material top surface;
d. a second lap cement layer in contact with the exposed top surface of the second waterproof, self-sealing, membrane;
e. a fiberglass and asphalt based sheathing with a top surface and an opposed bottom surface adhesively applied, opposed bottom surface down, to the second lap cement layer; and
f. a first lap cement layer in contact with the top surface of the fiberglass and asphalt based sheathing for receiving and adhesively securing the collector panel by its first waterproof, self-sealing, membrane opposed bottom surface and secondly secured with fasteners placed through the mounting screw guide tubes.
(e) copper quick connect fittings attached to the liquid inlet and outlet of each panel;
(f) copper pipe liquid connection manifolds for liquid distribution to and collection from panels arrays that are connected to the manifold by the copper quick connect fittings;
(g) a plastic raceway placed to receive electrical wiring from each panel or series panel string arranged in an array;
(h) quick-connect snap-in electrical connector plugs for the electrical interconnection of panels;
(i) quick-connect snap-in electrical connector receptacles to connect panels or series strings of panels to the raceway;
(j) a rain runoff collection trough connected to the lowest end of a slanted roof mounted solar panel or array of solar panels;
(k) solenoid valves and sprinkler head units connected between rows of panels that receive on/off control signals through their connected wiring; and
(l) an improved heat exchanger selected from the group consisting of: aluminum tubing heat exchanger; copper, thin-profile, water tank and aluminum, thin-profile, water tank.

22. The improved solar collector panel of claim 21 wherein the standard building construction material is exterior grade wood sheathing.

23. The improved solar collector panel of claim 21wherein the fasteners are stainless steel screws.

24. The improved solar collector panel of claim 21 wherein the solenoid valve and sprinkler head units on/off control signal originates from a controller device whose input analog temperature signal originates from each solar panel internal temperature sensor.

25. A method of installing improved solar collector panels with embedment, where local building codes require additional insulation, comprising the steps of:
assembling, at the factory, the collector panel;
assembling, at the factory, a first, waterproof, self-sealing membrane that includes a first adhesive layer in contact with the top surface of the first waterproof, self-sealing, membrane forming an interface;
adhesively securing, at the factory, the interface to the aluminum bottom plate of the solar collector by the first adhesive layer;
assembling, at the factory, a second, waterproof, self-sealing membrane that includes a second adhesive layer in contact with the opposed bottom surface of the second waterproof, self-sealing membrane;
adhesively securing, at the factory, the second waterproof, self-sealing membrane to the topside of roof or deck sheathing by the second adhesive layer forming the embedment;
installing the embedment to roofing joists by conventional construction fastening means;
placing a solid insulation board, opposed bottom surface down, on the embedment if required by local building codes;
applying a second layer of lap cement to the top surface of the solid insulation board;
covering the wet second layer of lap cement with a fiberglass and asphalt-based sheathing opposed bottom surface down;
applying a first layer of lap cement to the top surface of the fiberglass and asphalt-based sheathing;
placing the solar collector panel with the interface on the first layer of lap cement; and
securing the collector panel to the embedment with stainless steel screws, inserted through the mounting screw guide tubes, which are of selected length so that they penetrate only approximately half way through the roof or deck sheathing.

26. A method of installing improved solar collector panels with embedment, where additional insulation is not required, comprising the steps of:
assembling, at the factory, the collector panel;
assembling, at the factory, a first, waterproof, self-sealing membrane that includes a first adhesive layer in contact with the top surface of the first waterproof, self-sealing, membrane forming an interface;
adhesively securing, at the factory, the interface to the aluminum bottom plate of the solar collector by the first adhesive layer;
assembling, at the factory, a second, waterproof, self-sealing membrane that includes a second adhesive layer in contact with the opposed bottom surface of the second waterproof, self-sealing membrane;
adhesively securing, at the factory, the second waterproof, self-sealing membrane to the topside of roof or deck sheathing by the second adhesive layer forming the embedment;
installing the embedment to roofing joists by conventional construction fastening means;
applying a second layer of lap cement to the top surface of the second waterproof, self-sealing membrane;
covering the wet second layer of lap cement with a fiberglass and asphalt-based sheathing opposed bottom surface down;
applying a first layer of lap cement to the top surface of the fiberglass and asphalt-based sheathing;
placing the solar collector panel with the interface on the first layer of lap cement; and
securing the collector panel to the embedment with stainless steel screws, inserted through the mounting screw guide tubes, which are of selected length so that they penetrate only approximately half way through the roof or deck sheathing.
